(19) United States
(12) Patent Application Publication
(10) Pub. No.: US 2021/0028388 A1
(43) Pub. Date: Jan. 28, 2021

(54) OLED DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Qian JIANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/608,870

(22) PCT Filed: Aug. 5, 2019
(86) PCT No.: PCT/CN2019/099252

§ 371 Date: Oct. 28, 2019

(30) Foreign Application Priority Data
Jul. 22, 2019 (CN) 201910662649.2

(51) Int. Cl. H01L 51/52; H01L 27/32

(52) U.S. Cl. CPC H01L 51/525; H01L 27/3234; H01L 51/5253

(57) ABSTRACT

The present invention provides an organic light-emitting diode (OLED) display panel. The OLED display panel includes an array substrate, an OLED functional layer, and a thin film encapsulation layer. The OLED display panel has an opening region to be cut away. A dam surrounding the opening region is arranged between the array substrate and the OLED functional layer. The dam includes a barrier unit surrounding the opening region, and a cross-section of the barrier unit has an inverted trapezoidal shape. Because the cross-section of the barrier unit has an inverted trapezoidal shape, the OLED functional layer above the dam is disconnected at two sides of the dam. Therefore, after the opening region is cut away, ambient water/oxygen is prevented from entering a light-emitting pixel region from cutting surfaces of the opening region along a continuous common film layer, and a lifespan of the display panel is prolonged.

### 1. FIELD OF DISCLOSURE

The present invention relates to a field of display devices and in particular, to an organic light-emitting diode (OLED) display panel.

### 2. DESCRIPTION OF RELATED ART

In the flat panel display technology, organic light-emitting diode (OLED) displays have many advantages such as being thin and light, active illumination, fast response time, large viewing angles, a wide color gamut, high brightness, low power consumption, and flexible screens. OLED displays have gained great interest in the scientific research field and industries.

Nowadays, a “full screen” design has become the mainstream. At present, all suppliers are focused on developing full-screen products with relatively high screen ratios. For example, the iPhone X uses a notched screen design. The recently developed under-screen camera design is an O-cut screen design, as shown in FIG. 1, a camera is placed in a display panel 100. An O-shaped slot 500 in an active area (AA) of the display panel 100 is cut out for placing and exposing the camera, and one end of an IC (integrated circuit chip) is fixed below a screen. Compared with the notched screen design, the O-cut screen design is more advantageous for a full screen, and has more advantages on the market of mobile phones.

Although the O-cut design is closer to the full screen concept, it also faces technical difficulties, and it is particularly difficult to implement the O-cut design in the OLED flexible displays. In manufacturing of an OLED panel, metal masks used for depositing the respective film layers include a common metal mask and a fine metal mask. A size of a film layer formed by the common metal mask is close to a size of the screen and is usually slightly larger than an actual display area, and a certain margin is reserved to make the common metal mask have a completely hollowed out area corresponding to the display screen. The fine metal mask forms a film pattern whose size is close to that of a light-emitting sub-pixel, has a hollowed structure corresponding to the size of the sub-pixel, and partially forms a circular area which is not etched, not hollowed out, and arranged corresponding to an O-shaped slot corresponding to a camera.

With respect to the O-cut region, although elements and lines in an array section can bypass the O-cut region, it should be noted that a hole injection layer, a hole transport layer, an electron transport layer, an electron injection layer, and a cathode layer are generally formed by vapor deposition using the common metal mask in manufacturing of the OLED display. As a result, after the O-cut region is cut away, a portion of an organic layer in the OLED structure is exposed from cutting surfaces, and water/moisture will intrude from this position, leading to malfunction of the panel.

FIG. 2 is a schematic structural view illustrating a conventional OLED display panel before its O-cut region is cut out. As shown in FIG. 1, the OLED display panel includes an array substrate 5, an OLED functional layer 6 disposed on the array substrate 5, and a thin film encapsulation layer 7 covering the OLED functional layer 6 on the array substrate 5. The thin film encapsulation layer 7 comprises two inorganic barrier layers 71 and an organic buffer layer 72 disposed between the two inorganic barrier layers 71. The array substrate 5 is provided with two dams 8 for blocking the organic buffer layer 72, and the two circles of dams 8 are arranged along a direction from a peripheral region of an opening region 9 to be cut away toward the opening region 9. The OLED functional layer 6 includes an anode layer 61 disposed on the array substrate 5, a pixel defining layer 4 disposed on the array substrate 5 and the anode layer 61, a multi-layered organic functional layer 62 disposed on the pixel defining layer 4 and the anode layer 61, and a cathode layer 63 disposed on the multi-layered organic functional layer 62 and the pixel defining layer 4. The multi-layered organic functional layer 62 includes a light-emitting layer 65 formed by vapor deposition using a fine metal mask, and further includes a plurality of organic common film layers such as a hole injection layer, a hole transport layer, an electron transport layer, and an electron injection layer, wherein the organic common film layers each have a planar structure formed by vapor deposition using a common metal mask. A cathode layer 63 also has a planar structure and is a metal common film layer formed by vapor deposition using a common metal mask. Therefore, in subsequent processes, when an effective light-emitting region of the OLED display panel is cut along an edge of the opening region 9 to form a circular hole for placing the camera, cutting surfaces are formed in the multiple film layers. The multiple film layers include an organic common film layer and a metal common film layer formed in the OLED functional layer 6 by vapor deposition using a common metal mask, these film layers are easily eroded by ambient water/oxygen at the cutting surfaces. Moreover, since the film layers are directly connected to the inside of the light-emitting pixel region, ambient water/oxygen can erode along the continuous film layers to the light-emitting pixel region, thereby shortening a lifespan of a screen.

### SUMMARY

It is an objective of the present invention to provide an organic light-emitting diode display panel which can protect ambient water/oxygen from entering and eroding a light-emitting pixel region in the display panel and prolong a lifespan of the display panel.

Accordingly, the present invention provides an organic light-emitting diode (OLED) display panel, comprising:

an array substrate;

an OLED functional layer disposed on the array substrate; and

a thin film encapsulation layer covering the OLED functional layer on the array substrate;

wherein the OLED display panel comprises an opening region to be cut away; a dam surrounding the opening region is disposed between the array substrate and the OLED functional layer; and the dam comprises a barrier unit surrounding the opening region, and a cross-section of the barrier unit has an inverted trapezoidal shape.

The dam comprises one barrier unit.

The dam comprises two or more barrier units stacked one above the other.

The dam is made of an organic photoresist material, an inorganic non-metal material, or an inorganic metal material.

A height of the dam ranges from 1 micrometer to 100 micrometers, and an inclined angle of a side wall of the barrier unit ranges from 0 degree to 180 degrees.

The OLED display panel comprises one, two, or more dams.

The OLED functional layer comprises a first electrode layer disposed on the array substrate, a pixel defining layer disposed on the array substrate and the first electrode layer, an organic functional layer disposed on the first electrode layer and the pixel defining layer, and a second electrode layer disposed on the organic functional layer and the pixel defining layer.

The dam and the pixel defining layer are disposed in a same layer.

The thin film encapsulation layer comprises an inorganic barrier layer and an organic buffer layer which are alternately stacked; the dam keeps the buffer layer from extending into the opening region; and the inorganic barrier layer in the thin film encapsulation layer farthest from the OLED functional layer is a continuous structure above and at two sides of the dam.

A through hole is formed in the opening region, and the through hole penetrates an upper surface and a lower surface of the OLED display panel and is used for positioning a camera.

The present invention provides the OLED display panel comprising the array substrate, the OLED functional layer and the thin film encapsulation layer, wherein the OLED display panel is provided with the opening region to be cut away, the dam surrounding the opening region is disposed between the array substrate and the OLED functional layer, and the dam comprises the barrier unit having an inverted trapezoidal cross-section around the opening region. Because the cross-section of the barrier unit has an inverted trapezoidal shape, the OLED functional layer above the dam is disconnected at both sides of the dam during film formation processes. The present invention optimizes the structure of the dam around the opening region by making the cross-section of the blocking unit have an inverted trapezoidal shape. Therefore, the entire common film layer deposited by the common mask is cut off at both sides of the dam. As a result, after the opening region is cut away, ambient water/oxygen is prevented from entering the light-emitting pixel region of the display panel along the continuous common film layer from the cutting surfaces of the opening region, and thereby a lifespan of the display panel is prolonged.

The following description of the present invention is provided with reference to the accompanying drawings for ease of understanding of the features and technical contents of the present invention. The accompanying drawings are only provided for illustrative purposes and are not intended to limit the present invention.

### BRIEF DESCRIPTION OF DRAWINGS

The technical solution and other advantages of the present invention will be apparent from the following detailed description of embodiments of the present invention with reference to the accompanying drawings.

FIG. 1 is a schematic view illustrating a camera is placed in a display region of a display panel of a mobile phone;

FIG. 2 is a schematic structural view illustrating a conventional organic light-emitting diode (OLED) display panel before an O-cut region is cut away;

FIG. 3 is a schematic structural view illustrating an OLED display panel according to a first embodiment of the present invention; and

FIG. 4 is a schematic structural view illustrating the OLED display panel according to a second embodiment of the present invention.

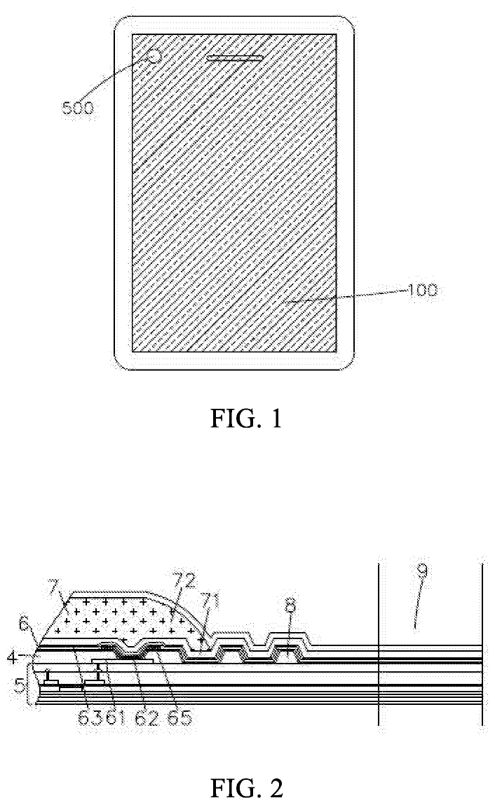

### DETAILED DESCRIPTION OF EMBODIMENTS

In order to clarify the technical solution and functions of the present invention, the following detailed description is made in conjunction with the preferable embodiments of the present invention and the accompanying drawings.

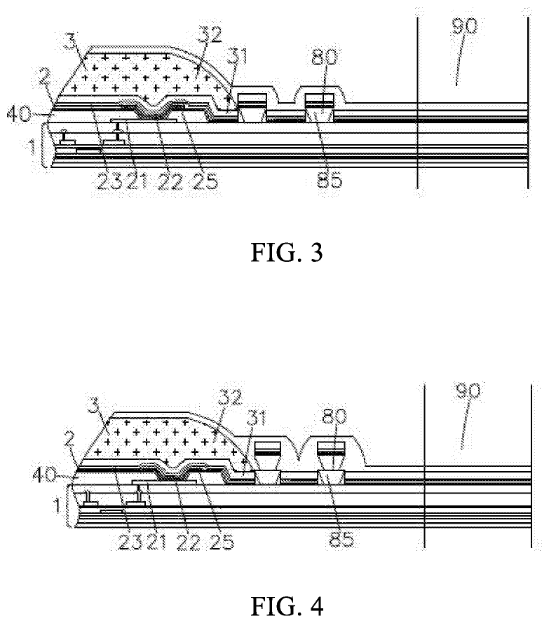

FIG. 3 shows an organic light-emitting diode (OLED) display panel according to a first embodiment of the present invention. The OLED display panel comprises an array substrate 1, an OLED functional layer 2 disposed on the array substrate 1, a thin film encapsulation layer 3 covering the OLED functional layer 2 on the array substrate 1.

The OLED display panel comprises an opening region 90 to be cut away. The opening region 90 is used to cut out a through hole. The through hole penetrates upper and lower surfaces of the OLED display panel and is used to position a camera.

A dam 80 surrounding the opening region 90 is disposed between the array substrate 1 and the OLED functional layer 2. There can be one, two, or three dams 3. The number of the dams 80 and an interval between the dams 80 are determined according to requirements of manufacturing processes. In the present embodiment, the number of the dams 80 is two, and the two dams 80 are disposed spaced apart from each other in a direction toward the opening region 90.

Specifically, in the present embodiment, each of the dams 80 is a single-layer structure including a barrier unit 85 surrounding the opening region 90, a cross-section of the barrier unit 85 has an inverted trapezoidal shape.

Specifically, the cross-section of the barrier unit 85 has an inverted trapezoidal shape, and a common film layer in the OLED functional layer 2, which is deposited over the dam 80 by using a common metal mask, is disconnected at two sides of the dam 80 when the common film layer is formed. After cutting of the opening region 90, ambient water/oxygen can be prevented from entering a light-emitting pixel region from cutting surfaces of the opening region 90 along the continuous common film layer in the OLED functional layer 2.

Specifically, the dam 80 may be made of an organic photoresist material, or an inorganic non-metal material such as silicon nitride (SiNx) and silicon oxide (SiOx), or an inorganic metal material such as molybdenum (Mo), titanium (Ti), and aluminum (Al).

A height of the dam 80 ranges from 1 micrometer to 100 micrometers. The height is determined according to actual needs of a manufacturing process.

An inclined angle of a side wall of the barrier unit 85 ranges from 0 degree to 180 degrees. The inclined angle is also determined according to actual needs of the manufacturing process.

The OLED functional layer comprises a first electrode layer 21 disposed on the array substrate 1, a pixel defining layer 40 disposed on the array substrate 1 and the first electrode layer 21, an organic functional layer 22 disposed on the first electrode layer 21 and the pixel defining layer 40, and a second electrode layer 23 disposed on the organic functional layer 22 and the pixel defining layer 40.

Specifically, the first electrode layer 21 and the second electrode layer 23 are an anode layer and a cathode layer, respectively, and the organic functional layer 22 includes a hole injection layer, a hole transport layer, and a light-emitting layer 25, an electron transport layer, and an electron injection layer which are stacked from bottom to top. The hole injection layer, the hole transport layer, the electron transport layer, the electron injection layer, and the cathode layer are common film layers deposited by using a common metal mask. The light-emitting layer 25 is deposited by using a fine metal mask. When the light-emitting layer 25 is deposited by using the fine metal mask, a pattern film is deposited only in a pixel opening area defined by the pixel defining layer 40.

Specifically, the array substrate 1 is a low temperature poly-silicon (LTPS) TFT array substrate or a metal-oxide semiconductor (MOS) TFT array substrate.

Specifically, the dam 80 is fabricated on the array substrate 1, and the dam 80 and the pixel defining layer 40 are formed in a same horizontal layer. Since the dam 80 has an inverted trapezoidal structure, the common film layer is disconnected at inclined side walls of the inverted trapezoidal structure when the common film layer in the OLED functional layer 2 is formed by using the common metal mask.

In detail, the thin film encapsulation layer 3 includes an inorganic barrier layer 31 and an organic buffer layer 32 which are alternately stacked, wherein the number of the inorganic barrier layers 31 is one more than the number of the organic buffer layers 32.

In detail, the inorganic barrier layer 31 is a silicon nitride layer or a silicon oxide layer having a thickness of lum to 2 um, which is a common film layer formed by using a common metal mask and extended from the light-emitting pixel region of the OLED display panel to the opening region 90. In the thin film encapsulation layer 3, the lowermost inorganic barrier layer 31 in contact with the OLED functional layer 2 may have a portion which is still continuous and have another portion which is disconnected at the dam 80. The organic buffer layer 32 is formed by inkjet printing to form the light-emitting pixel region outside the opening region 90. A thickness of the organic buffer layer 32 is 1 μm to 20 μm. In the thin film encapsulation layer 3, the uppermost inorganic barrier layer 31 away from the OLED functional layer 2 is still continuous above and at two sides of the dam 80, and the uppermost inorganic barrier layer 31 continuously covers the OLED functional layer 2 at the dam 80.

Specifically, when the opening region 90 of the OLED panel is cut to form an opening, the common film layer is exposed from cutting surfaces of the opening region 90. Ambient water/oxygen can erode the exposed OLED functional layer 2 from the cutting surfaces, and continuously erode in a direction toward the light-emitting pixel region, but water/oxygen cannot pass through the dam 80 of an inverted trapezoidal shape, because the common film layer of the OLED functional layer 2 is disconnected at the dam 80, and an etching path is thus cut off there. Therefore, the OLED functional layer 2 in the light-emitting pixel region can be protected.

The OLED display panel of the present invention optimizes the structure of the dam 80 around the opening region 90 by making the cross-section of the barrier unit 85 have an inverted trapezoidal shape, thereby the film layer deposited through the common metal mask is cut at both sides of the dam 80. Consequently, after the opening region 90 is cut away, ambient water/oxygen is prevented from invading an active area of the display panel from the cutting surfaces of the opening region 90 along the continuous common film layer of the OLED functional layer 2, thereby prolonging a lifespan of the display panel.

FIG. 3 is a schematic structural view illustrating the OLED display panel according to a second embodiment of the present invention. The difference between the present embodiment and the first embodiment is that each of the dams 80 has a double-layered structure and comprises two barrier units 85 stacked on each other.

In addition, the two dams 80 can be of different structures. One of the two dams 80 is a single layer structure which includes one barrier unit 85. The other dam 80 is a double-layered or multilayer structure which includes two or more barrier units 85 stacked on each other to form dams 80 of different heights to cut off the common film layer.

In summary, the present invention provides the OLED display panel comprising the array substrate, the OLED functional layer and the thin film encapsulation layer, wherein the OLED display panel is provided with the opening region to be cut away, the dam surrounding the opening region is disposed between the array substrate and the OLED functional layer, and the dam comprises the barrier unit having an inverted trapezoidal cross-section around the opening region. Because the cross-section of the barrier unit has an inverted trapezoidal shape, the OLED functional layer above the dam is disconnected at both sides of the dam during film formation processes. The present invention optimizes the structure of the dam around the opening region by making the cross-section of the blocking unit have an inverted trapezoidal shape. Therefore, the entire common film layer deposited by the common mask can be cut off at both sides of the dam.

As a result, after the opening region is cut away, ambient water/oxygen is prevented from entering the light-emitting pixel region of the display panel along the continuous common film layer from the cutting surfaces of the opening region, and thereby a lifespan of the display panel is prolonged.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. An organic light-emitting diode (OLED) display panel, comprising:
an array substrate;
an OLED functional layer disposed on the array substrate; and
a thin film encapsulation layer covering the OLED functional layer on the array substrate;
wherein the OLED display panel comprises an opening region to be cut away; a dam surrounding the opening region is disposed between the array substrate and the OLED functional layer; and the dam comprises a barrier unit surrounding the opening region, and a cross-section of the barrier unit has an inverted trapezoidal shape.

2. The OLED display panel according to claim 1, wherein the dam comprises one barrier unit.

3. The OLED display panel according to claim 1, wherein the dam comprises two or more barrier units stacked one above the other.

4. The OLED display panel according to claim 1, wherein the dam is made of an organic photoresist material, an inorganic non-metal material, or an inorganic metal material.

5. The OLED display panel according to claim 1, wherein a height of the dam ranges from 1 micrometer to 100 micrometers, and an inclined angle of a side wall of the dam ranges from 0 degree to 180 degrees.

6. The OLED display panel according to claim 1, wherein the OLED display panel comprises one, two, or more dams.

7. The OLED display panel according to claim 1, wherein the OLED functional layer comprises a first electrode layer disposed on the array substrate, a pixel defining layer disposed on the array substrate and the first electrode layer, an organic functional layer disposed on the first electrode layer and the pixel defining layer, and a second electrode layer disposed on the organic functional layer and the pixel defining layer.

8. The OLED display panel according to claim 7, wherein the dam and the pixel defining layer are disposed in a same layer.

9. The OLED display panel according to claim 1, wherein the thin film encapsulation layer comprises an inorganic barrier layer and an organic buffer layer which are alternately stacked; the dam keeps the buffer layer from extending into the opening region; and the inorganic barrier layer in the thin film encapsulation layer farthest from the OLED functional layer is a continuous structure above and at two sides of the dam.

10. The OLED display panel according to claim 1, wherein a through hole is formed in the opening region, and the through hole penetrates an upper surface and a lower surface of the OLED display panel and is used for positioning a camera.
